(19) United States
(12) Patent Application Publication
(10) Pub. No.: US 2011/0214731 A1
(43) Pub. Date: Sep. 8, 2011

(54) Solar Cell and Method for Manufacturing the Same

(76) Inventor: Won Seok PARK, Seoul (KR)

(21) Appl. No.: 13/041,045

(22) Filed: Mar. 4, 2011

(30) Foreign Application Priority Data
Mar. 5, 2010 (KR) 10-2010-0019712

(51) Int. Cl. H01L 31/0224; H01L 31/0352

(52) U.S. Cl. 136/256; 438/87; 257/E31.032

(57) ABSTRACT

Disclosed is a solar cell and a method for manufacturing the same, which facilitates to prevent residual matters from remaining between first and second electrodes, to minimize a substrate-sagging problem even though plural layers are deposited on a substrate under high-temperature conditions, and to minimize the number of times of laser-scribing process. The solar cell comprises a substrate including a through-hole; a first electrode on one surface of the substrate, wherein one end of the first electrode is extended to an inner surface of the through-hole; a semiconductor layer on the first electrode; a second electrode on the semiconductor layer, wherein one end of the second electrode is extended to the inner surface of the through-hole; and a connecting portion for electrically connecting the one end of the first electrode with the one end of the second electrode.

### CROSS REFERENCE TO RELATED APPLICATIONS

This application claims the benefit of the Korean Patent Application No. P2010-0019712 filed on Mar. 5, 2010, which is hereby incorporated by reference as if fully set forth herein.

### BACKGROUND OF THE INVENTION

1. Field of the Invention

The present invention relates to a solar cell, and more particularly, to a thin film type solar cell.

2. Discussion of the Related Art

A solar cell with a property of semiconductor converts a light energy into an electric energy.

The solar cell is formed in a PN junction structure where a positive (P)-type semiconductor makes a junction with a negative (N)-type semiconductor. When solar ray is incident on the solar cell with the PN junction structure, holes (+) and electrons (−) are generated in the semiconductor owing to the energy of the solar ray. By an electric field generated in the PN junction, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. The thin film type solar cell is advantageous in that its manufacturing cost is relatively lower than that of the wafer type solar cell.

Hereinafter, a related art thin film type solar cell will be described with reference to the accompanying drawings.

FIG. 1 is a cross section view illustrating a related art thin film type solar cell.

As shown in FIG. 1, the related art thin film type solar cell includes a substrate 10, a first electrode 20, a semiconductor layer 30, and a second electrode 40.

The first electrode 20 is formed on the substrate 10. The plurality of first electrodes 20 are provided at fixed intervals by each first separating channel 25 interposed in-between.

The semiconductor layer 30 is formed on the first electrode 20. The plurality of semiconductor layers 30 are provided at fixed intervals by each contact portion 35 or second separating channel 45 interposed in-between.

The second electrode 40 is formed on the semiconductor layer 30. The plurality of second electrodes 40 are provided at fixed intervals by each second separating channel 45 interposed in-between. Herein, the second electrode 40 is electrically connected with the first electrode 20 via the contact portion 35.

The related art thin film type solar cell has a structure where a plurality of unit cells are electrically connected in series by the electric connection of the first and second electrodes 20 and 40 via the contact portion 35. This series connection structure enables to decrease the size of electrode, to thereby decrease resistance.

FIGS. 2A to 2F are cross section views illustrating a method for manufacturing the related art thin film type solar cell.

First, as shown in FIG. 2A, a first electrode layer 20a is formed on the substrate 10.

Then, as shown in FIG. 2B, the first separating channel 25 is formed by removing a predetermined portion from the first electrode layer 20a. Thus, the plurality of first electrodes 20 are provided at fixed intervals by each first separating channel 25 interposed in-between. The process for removing the predetermined portion from the first electrode layer 20a may be carried out by a laser-scribing process.

Then, as shown in FIG. 2C, the semiconductor layer 30 is formed on an entire surface of the substrate 10 including the first electrode 20.

As shown in FIG. 2D, the contact portion 35 is formed by removing a predetermined portion from the semiconductor layer 30. The process for removing the predetermined portion from the semiconductor layer 30 may be carried out by a laser-scribing process.

As shown in FIG. 2E, a second electrode layer 40a is formed on the entire surface of the substrate 10 including the semiconductor layer 30.

As shown in FIG. 2F, the second separating channel 45 is formed by removing a predetermined portion from the second electrode layer 40a and semiconductor layer 30. Thus, the plurality of second electrodes 40 are provided at fixed intervals by each second separating channel 45 interposed in-between. The process for removing the predetermined portion from the second electrode layer 40a and semiconductor layer 30 may be carried out by a laser-scribing process.

However, the related art thin film type solar cell has the following disadvantages.

First, if the contact portion 35 is formed by the above laser-scribing process shown in FIG. 2D, residual matters including the semiconductor materials may remain in the contact portion 35. Under such circumstances, if the process of FIGS. 2E and 2F is carried out, the contact resistance between the first and second electrodes 20 and 40 may be increased due to the residual matters, which might cause the deteriorated efficiency in the solar cell.

The plural layers including the first electrode layer 20a are deposited on the substrate 10 under the high-temperature condition. If the deposition process is carried out under the high-temperature condition, the substrate 10 of the thin film may be sagged. Furthermore, if the additional layers are deposited on the sagging substrate 10, the additionally-provided layers may be deteriorated in uniformity.

For forming the first separating channel 25, the contact portion 35, and the second separating channel 45, the laser-scribing process is carried out three times, whereby the manufacturing process is complicated, and the manufacturing time is also increased. In addition, three scribing apparatuses are necessarily required so that the manufacturing cost is increased.

### SUMMARY OF THE INVENTION

Accordingly, the present invention is directed to a solar cell and a method for manufacturing the same that substantially obviates one or more problems due to limitations and disadvantages of the related art.

An object of the present invention is to provide a solar cell and a method for manufacturing the same, which facilitates to prevent residual matters from remaining between first and second electrodes, to minimize a substrate-sagging problem even though plural layers are deposited on a substrate under high-temperature conditions, and to minimize the number of times of laser-scribing process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a solar cell comprising: a substrate including a through-hole; a first electrode on one surface of the substrate, wherein one end of the first electrode is extended to an inner surface of the through-hole; a semiconductor layer on the first electrode; a second electrode on the semiconductor layer, wherein one end of the second electrode is extended to the inner surface of the through-hole; and a connecting portion for electrically connecting the one end of the first electrode with the one end of the second electrode.

In another aspect of the present invention, there is provided a method for manufacturing a solar cell comprising: preparing a substrate including a through-hole; forming a first electrode layer on one surface of the substrate including an inner surface of the through-hole; forming a first electrode provided at a predetermined interval from a first separating channel by removing a predetermined portion from the first electrode layer, wherein one end of the first electrode is formed on the inner surface of the through-hole; forming a semiconductor layer on the first electrode; forming a second electrode layer on the semiconductor layer; forming a second electrode provided at a predetermined interval from a second separating channel by removing a predetermined portion from the second electrode layer, wherein one end of the second electrode is formed on the inner surface of the through-hole; and forming a connecting portion for electrically connecting the one end of the first electrode with the one end of the second electrode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art thin film type solar cell;

FIGS. 2A to 2F are cross section views illustrating a method for manufacturing a related art thin film type solar cell;

FIG. 3A is a plane view illustrating a solar cell according to one embodiment of the present invention; FIG. 3B is a cross section view along A-A of FIG. 3A; and FIG. 3C is a cross section view along B-B of FIG. 3A;

FIG. 4A is a plane view illustrating a solar cell according to another embodiment of the present invention; FIG. 4B is a cross section view along A-A of FIG. 4A; and FIG. 4C is a cross section view along B-B of FIG. 4A;

FIGS. 5A to 5G are cross section views illustrating a method for manufacturing a solar cell according to one embodiment of the present invention; and

FIGS. 6A to 6G are cross section views illustrating a method for manufacturing a solar cell according to another embodiment of the present invention.

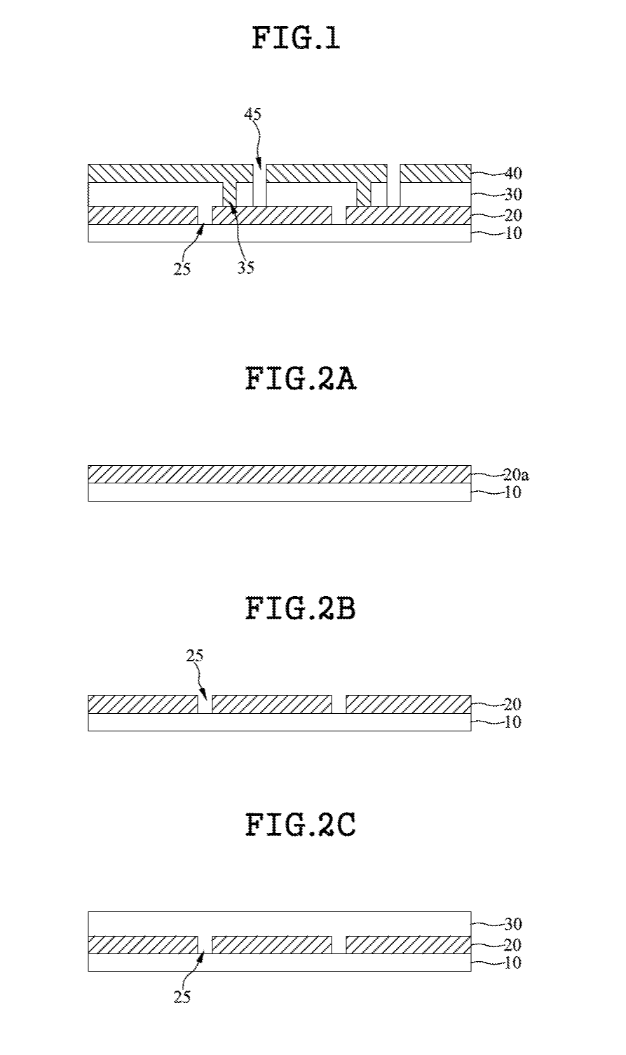

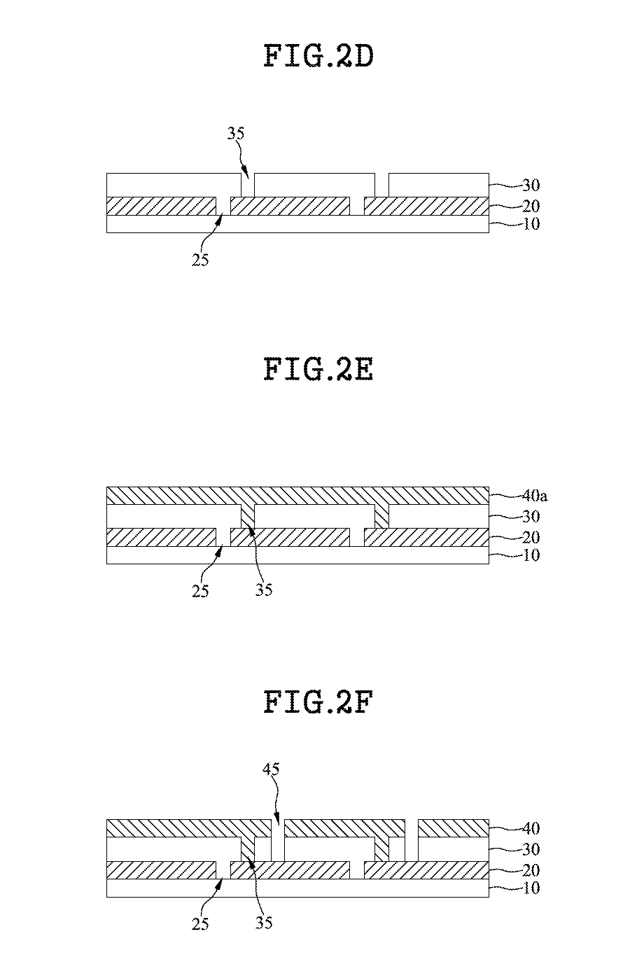

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a solar cell according to the present invention and a method for manufacturing the same will be described with reference to the accompanying drawings.

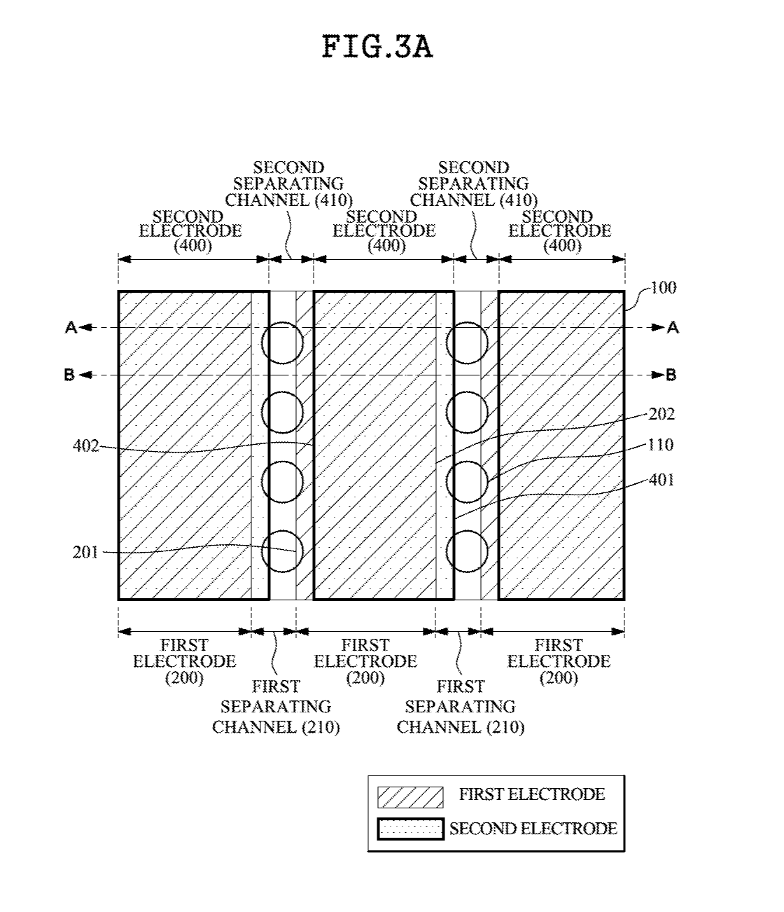

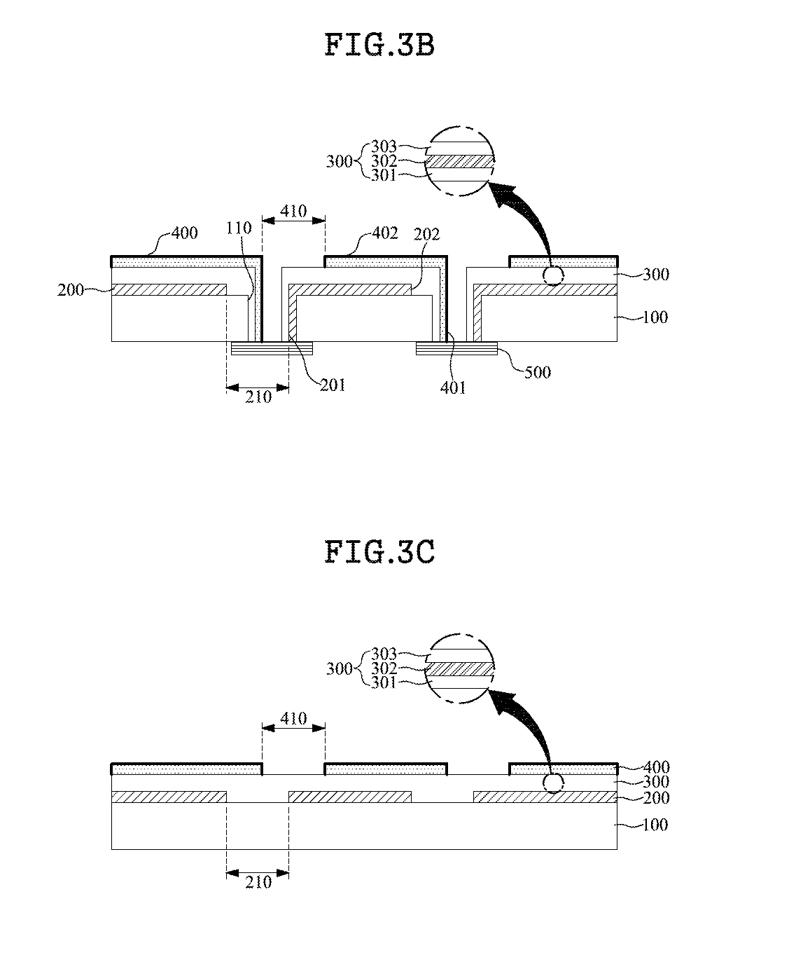

FIG. 3A is a plane view illustrating a solar cell according to one embodiment of the present invention, FIG. 3B is a cross section view along A-A of FIG. 3A, and FIG. 3C is a cross section view along B-B of FIG. 3A.

As shown in FIGS. 3A to 3C, the solar cell according to one embodiment of the present invention includes a substrate 100, a first electrode 200, a semiconductor layer 300, a second electrode 400, and a connecting portion 500.

The substrate 100 may be a flexible substrate. In this case, it is possible to realize a flexible solar cell which is easily applied to a mobile device. The flexible substrate may be formed of polyimide or polyamide. Especially, in case of the flexible solar cell, the substrate 100 may be positioned at the outermost rear part of the solar cell. Thus, the substrate 100 may be formed of an opaque material as well as a transparent material.

A plurality of through-holes 110 are formed in the substrate 100. The first and second electrodes 200 and 400 may be electrically connected to each other via the through-hole 110, whereby a plurality of unit cells may be electrically connected in series. This will be easily understood with reference to the following explanation about the connecting portion 500.

The plurality of through-holes 110 may be provided in such a manner that they may be arranged in a predetermined direction. Especially, the plurality of through-holes 110 may be arranged at fixed intervals along a straight line. According as the straight line of the through-holes 110 is repetitively arranged, it makes a stripe pattern. The plurality of unit cells may be formed based on the arrangement pattern of the through-holes 110.

The first electrode 200 is formed on one surface of the substrate 100, for example, an upper surface of the substrate 100. The plurality of first electrodes 200 may be provided at fixed intervals by each first separating channel 210 interposed in-between.

The first separating channel 210 is formed in parallel to the arrangement direction of the plural through-holes 110 in the substrate 100. Especially, the first separating channel 210 is partially overlapped with a predetermined portion of the through-hole 110. The plurality of through-holes 110 are formed in such a manner that they are overlapped with the predetermined portion of the first separating channel 210. By the above structure of the first separating channel 210, the respective first electrodes 200 may have the following structure.

One end 201 of each of the plural first electrodes 200 is extended to an inner surface of the through-hole 110 provided in the substrate 100. Especially, the one end 201 of the first electrode 200 is formed in a partial portion of the inner surface of the through-hole 110; and the other end 202 of the first electrode 200 is not extended to the inner surface of the through-hole 110. Thus, the other end 202 of the first electrode 200 is formed on the one surface of the substrate 100, for example, the upper surface of the substrate 100.

The first electrode 200 may be formed of metal such as Ag, Al, Ag+Mo, Ag+Ni, or Ag+Cu, but it is not limited to these examples. For instance, the first electrode 200 may be formed of a transparent conductive material such as ZnO; ZnO doped with a material including Group III elements in the periodic table (for example, ZnO:B, ZnO:Al); ZnO doped with a material including hydrogen elements (for example, ZnO:H); SnO₂; SnO₂:F; or ITO (Indium Tin Oxide).

The semiconductor layer 300 is formed on the plurality of first electrodes 200. In addition, the semiconductor layer 300 is extended to the inner surface of the through-hole 110 provided in the substrate 100. Especially, the semiconductor layer 300 may be formed in the entire inner surface of the through-hole 110. The semiconductor layer 300 may be formed on the one end 201 of the first electrode 200 in the inner surface of the through-hole 110, and also may be formed under one end 401 of the second electrode 400.

The semiconductor layer 300 may be formed of a silicon-based material such as amorphous silicon or crystalline silicon, but it is not limited to these examples. For instance, the semiconductor layer 300 may be formed of a compound such as CIGS (CuInGaSe2).

The semiconductor layer 300 may be formed in an NIP structure where N(negative)-type semiconductor layer, I(intrinsic)-type semiconductor layer, and P(positive)-type semiconductor layer are deposited in sequence. In the semiconductor layer 300 with the NIP structure, depletion is generated in the I-type semiconductor layer by the P-type semiconductor layer and the N-type semiconductor layer, whereby an electric field occurs therein. Thus, electrons and holes generated by the solar ray are drifted by the electric field, and the drifted electrons and holes are collected in the N-type semiconductor layer and the P-type semiconductor layer, respectively.

The reason why the semiconductor layer 300 is formed in the NIP structure is because a drift mobility of the hole is less than a drift mobility of the electron. In order to maximize the efficiency in collection of the incident solar ray, the P-type semiconductor layer is provided adjacent to a light-incidence face.

As known from the enlarged views of FIGS. 3B and 3C, the semiconductor layer 300 may be formed in a tandem structure where a first semiconductor layer 301, a buffer layer 302, and a second semiconductor layer 303 are deposited in sequence.

Both the first semiconductor layer 301 and the second semiconductor layer 303 may be formed in the NIP structure where the N-type semiconductor layer, the I-type semiconductor layer, and the P-type semiconductor layer are deposited in sequence.

The first semiconductor layer 301 may be formed in the NIP structure of amorphous semiconductor material, and the second semiconductor layer 303 may be formed in the NIP structure of microcrystalline semiconductor material. The amorphous semiconductor material is characterized by absorption of short-wavelength light, and the microcrystalline semiconductor material is characterized by absorption of long-wavelength light. A mixture of the amorphous semiconductor material and the microcrystalline semiconductor material enables to enhance light-absorbing efficiency, but it is not limited to this type of mixture. That is, the first semiconductor layer 301 may be made of amorphous semiconductor/germanium material, or microcrystalline semiconductor material; and the second semiconductor layer 303 may be made of amorphous semiconductor material, amorphous semiconductor/germanium material, or microcrystalline semiconductor material.

The buffer layer 302 is interposed between the first and second semiconductor layers 301 and 303, wherein the buffer layer 302 enables a smooth drift of electron and hole by a tunnel junction. The buffer layer 302 may be formed of a transparent material, for example, ZnO; ZnO doped with a material including Group III elements in the periodic table (for example, ZnO:B, ZnO:Al); ZnO doped with a material including hydrogen elements (for example, ZnO:H); SnO₂; SnO₂:F; or ITO (Indium Tin Oxide).

In addition to the aforementioned tandem structure, the semiconductor layer 300 may be formed in a triple structure. In this triple structure, each buffer layer is interposed between each of first, second and third semiconductor layers included in the semiconductor layer 300.

The second electrode 400 is formed on the semiconductor layer 300. The plurality of second electrodes 400 may be provided at fixed intervals by each second separating channel 410 interposed in-between.

The second separating channel 410 is formed in parallel to the arrangement direction of the plural through-holes 110 in the substrate 100. Especially, the second separating channel 410 is partially overlapped with a predetermined portion of the through-hole 110. That is, the plurality of through-holes 110 are formed in such a manner that they overlapped with a predetermined portion of the second separating channel 410. Also, the second separating channel 410 is partially overlapped with the first separating channel 210. That is, the second separating channel 410 is overlapped with a predetermined portion of the first separating channel 210. By the above structure of the second separating channel 410, the respective second electrodes 400 may have the following structure.

One end 401 of each of the plural second electrodes 400 is extended to an inner surface of the through-hole 110 provided in the substrate 100. Especially, the one end 401 of the second electrode 400 is formed in the other portion of the inner surface of the through-hole 110, on which the one end 201 of the first electrode 200 is not formed. The other end 402 of the second electrode 400 is not extended to the inner surface of the through-hole 110, whereby the other end 402 of the second electrode 400 is formed on one surface of the substrate 100, for example, the upper surface of the substrate 100.

The solar ray may be incident on the second electrode 400. In this case, the second electrode 400 may be formed of a transparent conductive material. For example, the second electrode 400 may be formed of a transparent conductive material such as ZnO; ZnO doped with a material including Group III elements in the periodic table (for example, ZnO:B, ZnO:Al); ZnO doped with a material including hydrogen elements (for example, ZnO:H); SnO₂; SnO₂:F; or ITO (Indium Tin Oxide).

The connecting portion 500 enables to electrically connect the plural unit cells in series by the electric connection of the first and second electrodes 200 and 400. In more detail, the connecting portion 500 is formed on the other surface of the substrate 100. Especially, the connecting portion 500 is connected with the one end 201 of the first electrode 200 extended to the inner surface of the through-hole 110 of the substrate 100, and is also connected with the one end 401 of the second electrode 400 extended to the inner surface of the through-hole 110 of the substrate 100, whereby the first electrode 200 and the second electrode 400 are electrically connected with each other. Thus, the connecting portion 500 may be formed of a conductive metal material such as Ag.

The connecting portion 500 is extended in the same direction as the plurality of through-holes 110 provided in the substrate 100, whereby the connecting portion 500 is respectively connected with the one end 201 of the first electrode 200, and the one end 401 of the second electrode 400 extended to the inner surface of the through-hole 110 of the substrate 100.

Although not shown, a transparent conductive layer may be additionally formed between the first electrode 200 and the semiconductor layer 300, or between the second electrode 400 and the semiconductor layer 300. Owing to the transparent conductive layer, the electron or hole generated in the semiconductor layer 300 may be easily drifted toward the first or second electrode 200 or 400.

The transparent conductive layer may be formed of a transparent conductive material such as ZnO; ZnO doped with a material including Group III elements in the periodic table (for example, ZnO:B, ZnO:Al); ZnO doped with a material including hydrogen element (for example, ZnO:H); SnO₂; SnO₂:F; or ITO (Indium Tin Oxide).

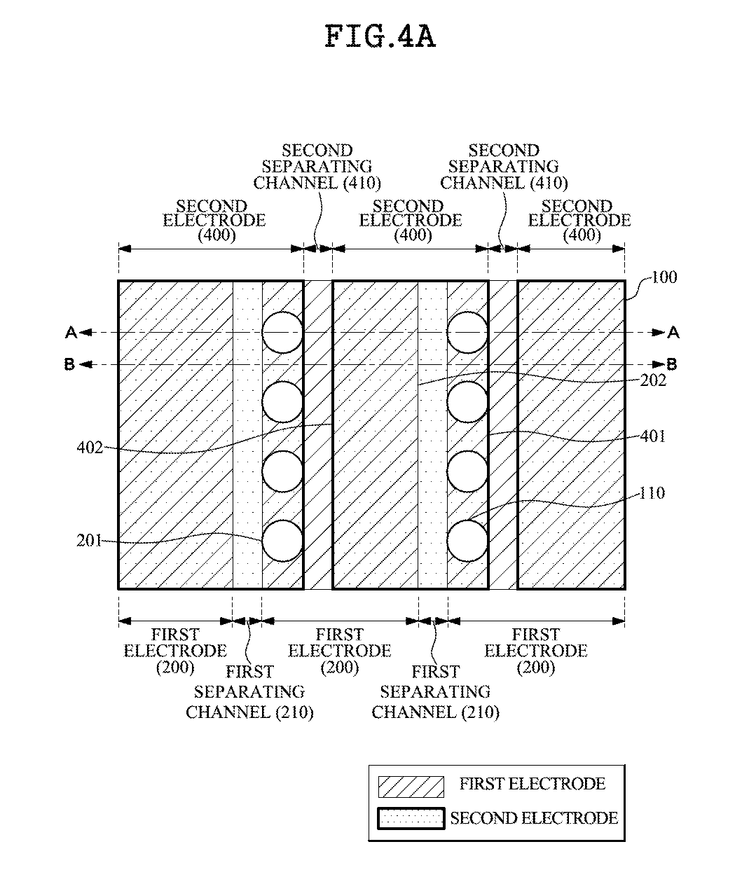

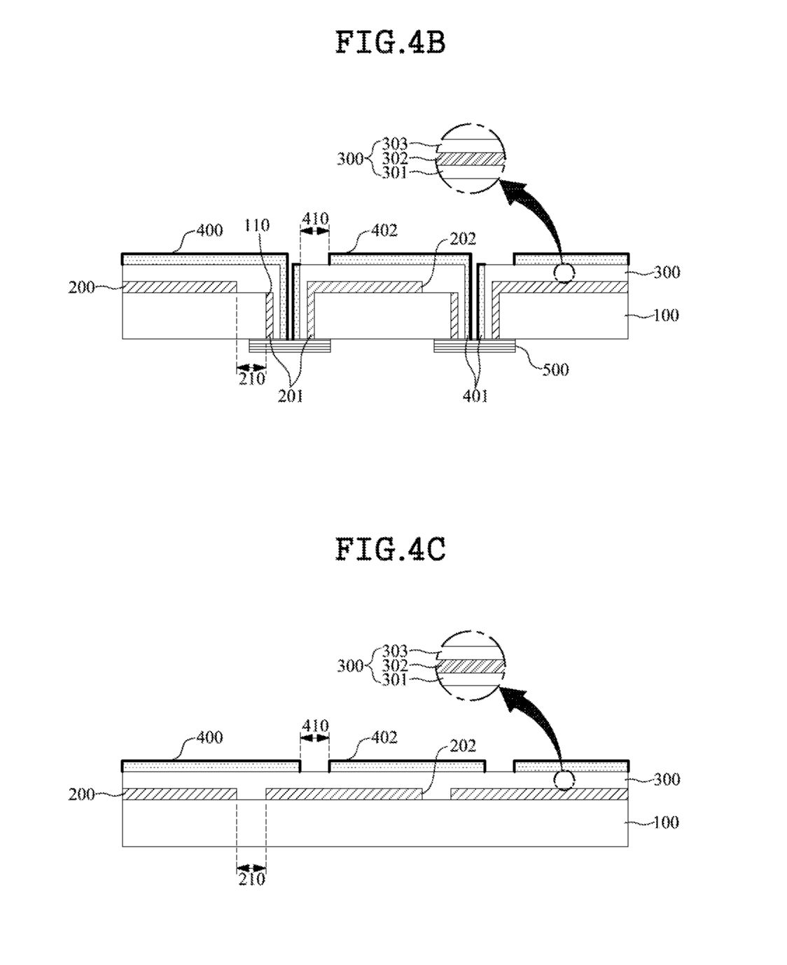

FIG. 4A is a plane view illustrating a solar cell according to another embodiment of the present invention, FIG. 4B is a cross section view along A-A of FIG. 4A, and FIG. 4C is a cross section view along B-B of FIG. 4A.

Except that first and second electrodes 200 and 400 are changed in structure by changing positions of first and second separating channels 210 and 410, the solar cell according to another embodiment of the present invention, shown in FIGS. 4A to 4C, is identical in structure to the solar cell shown in FIGS. 3A to 3C. Thus, the same reference numbers will be used throughout the drawings to refer to the same or like parts, and a detailed explanation for the same parts will be omitted.

As shown in FIGS. 4A to 4C, the solar cell according to another embodiment of the present invention includes a substrate 100, a first electrode 200, a semiconductor layer 300, a second electrode 400, and a connecting portion 500.

A plurality of through-holes 110 are formed in the substrate 100, wherein the plurality of through-holes 110 are arranged at fixed intervals along a straight line.

The first electrode 200 is formed on one surface of the substrate 100, for example, an upper surface of the substrate 100. The plurality of first electrodes 200 are provided at fixed intervals by each first separating channel 210 interposed in-between.

The first separating channel 210 is formed in parallel to the arrangement direction of the plural through-holes 110 in the substrate 100. Especially, the first separating channel 210 is not overlapped with the through-hole 110. By the above structure of the first separating channel 210, the respective first electrodes 200 may have the following structure.

One end 201 of each of the plural first electrodes 200 is extended to an inner surface of the through-hole 110 provided in the substrate 100. Especially, the one end 201 of the first electrode 200 is formed on the entire inner surface of the through-hole 110. Also, the other end 202 of the first electrode 200 is not extended to the inner surface of the through-hole 110. Thus, the other end 202 of the first electrode 200 is formed on one surface of the substrate 100, for example, the upper surface of the substrate 100.

The semiconductor layer 300 is formed on the plurality of first electrodes 200. Especially, the semiconductor layer 300 may be formed on the entire inner surface of the through-hole 110. Also, the semiconductor layer 300 may be formed on the one end 201 of the first electrode 200 in the inner surface of the through-hole 110, and also may be formed under one end 401 of the second electrode 400.

The semiconductor layer 300 may be formed in an NIP structure. Also, the semiconductor layer 300 may be formed in a tandem structure where a first semiconductor layer 301, a buffer layer 302, and a second semiconductor layer 303 are deposited in sequence.

The second electrode 400 is formed on the semiconductor layer 300. The plurality of second electrodes 400 are provided at fixed intervals by each second separating channel 410 interposed in-between.

The second separating channel 410 is formed in parallel to the arrangement direction of the plural through-holes 110 in the substrate 100. Especially, the second separating channel 410 is not overlapped with the through-hole 110. Also, the second separating channel 410 is not overlapped with the first separating channel 210.

By the above structure of the second separating channel 410, the respective second electrodes 400 may have the following structure.

One end 401 of each of the plural second electrodes 400 is extended to the inner surface of the through-hole 110 provided in the substrate 100. Especially, the one end 401 of the second electrode 400 is formed in the entire inner surface of the through-hole 110. Also, the other end 402 of the second electrode 400 is not extended to the inner surface of the through-hole 110. Thus, the other end 402 of the second electrode 400 is formed on one surface of the substrate 100, for example, the upper surface of the substrate 100.

The connecting portion 500 is formed on the other surface of the substrate 100. Especially, the connecting portion 500 is respectively connected with the one end 201 of the first electrode 200, and the one end 401 of the second electrode 400 extended to the inner surface of the through-hole 110 of the substrate 100. Eventually, a plurality of unit cells are electrically connected in series by electrically connecting the first and second electrodes 200 and 400 to each other.

Although not shown, a transparent conductive layer may be additionally formed between the first electrode 200 and the semiconductor layer 300, or between the second electrode 400 and the semiconductor layer 300.

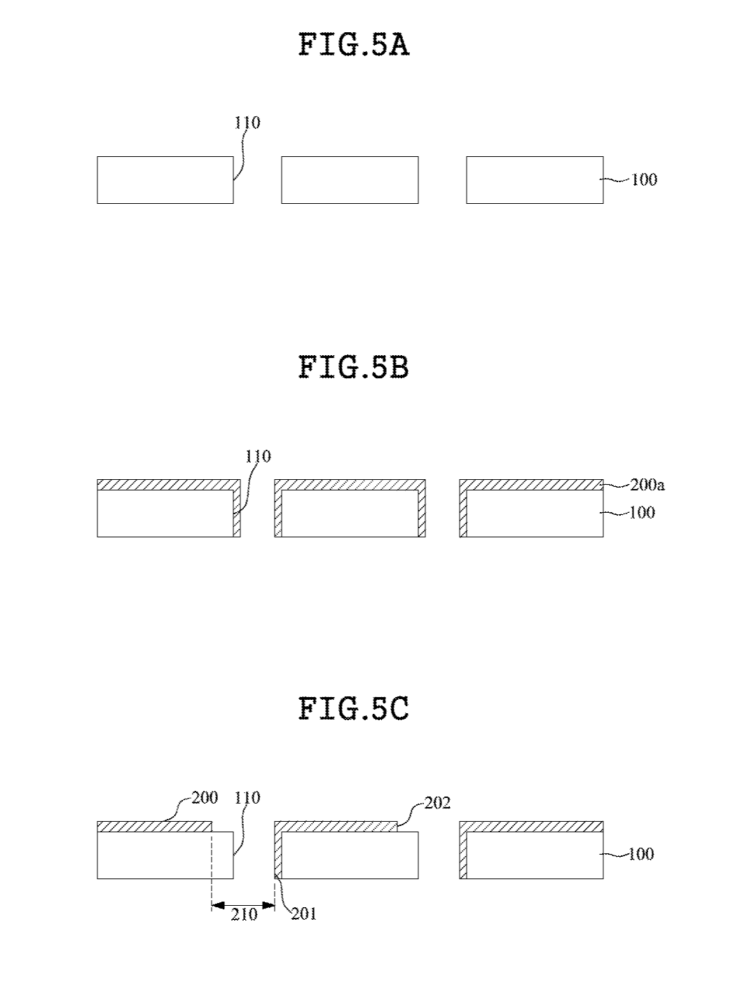

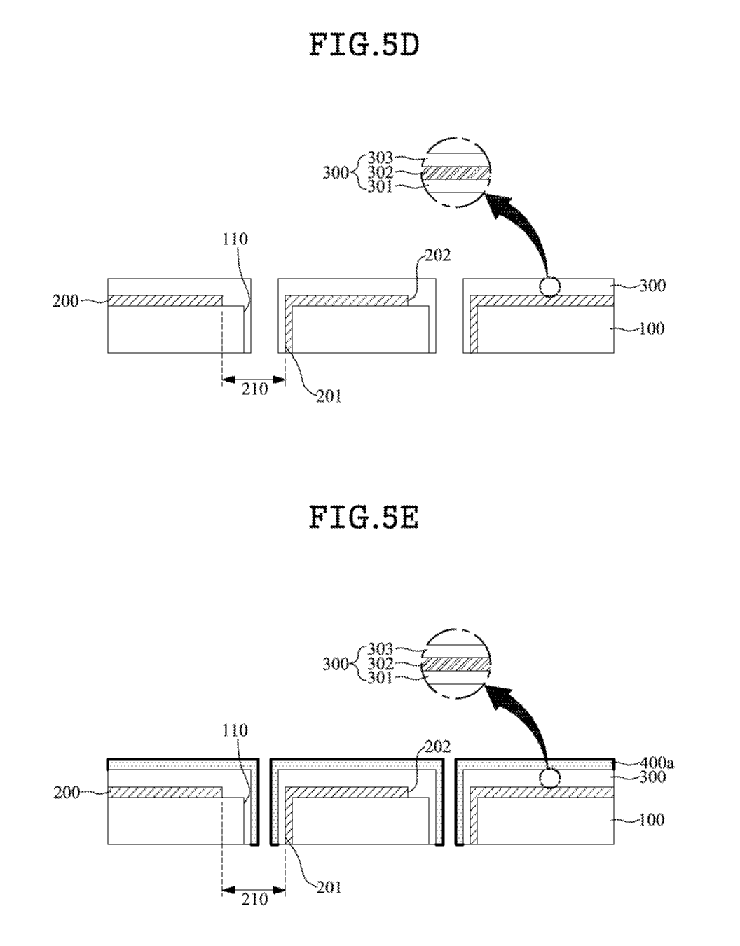

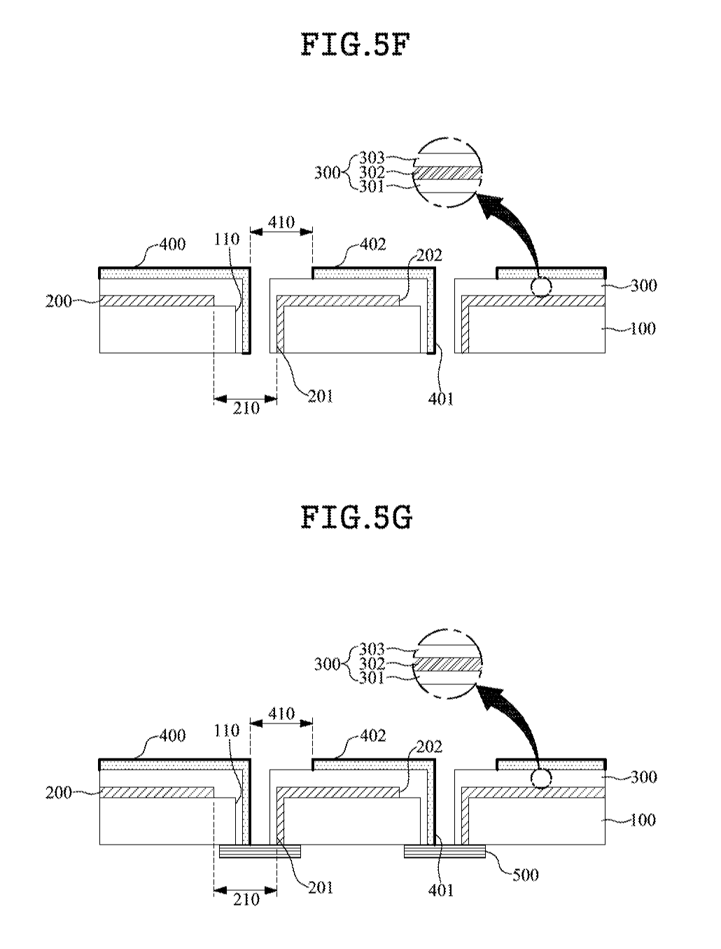

FIGS. 5A to 5G are cross section views illustrating a method for manufacturing the solar cell according to one embodiment of the present invention. FIGS. 5A to 5G illustrate a manufacturing process of the solar cell shown in FIGS. 3A to 3C, which are cross section views along A-A of FIG. 3A.

First, as shown in FIG. 5A, the substrate 100 including the through-holes 110 is prepared.

The through-holes 110 included in the substrate 100 may be obtained by various methods generally known to those skilled in the art, for example, mechanical processing method. The substrate 100 and the through-hole 110 are the same as the aforementioned those, whereby a detailed explanation for the substrate 100 and the through-hole 110 will be omitted.

Then, as shown in FIG. 5B, a first electrode layer 200a is formed on the one surface of the substrate 100, for example, the upper surface of the substrate 100.

The first electrode layer 200a may be formed of a metal material such as Ag, Al, Ag+Mo, Ag+Ni, and Ag+Cu, or a transparent conductive material such as ZnO; ZnO doped with a material including Group III elements in the periodic table (for example, ZnO:B, ZnO:Al); ZnO doped with a material including hydrogen elements (for example, ZnO:H); SnO₂; SnO₂:F; or ITO (Indium Tin Oxide) by a printing method such as a screen-printing method, inkjet-printing method, gravure-printing method, or micro-contact printing method; by MOCVD (Metal Organic Chemical Vapor Deposition); or by sputtering.

When carrying out the printing process, the MOCVD process, or the sputtering process, the first electrode layer 200a may be formed on the inner surface of the through-hole 110 provided in the substrate 100.

As shown in FIG. 5C, the first separating channel 210 is formed by removing a predetermined portion from the first electrode layer 200a. Thus, the plurality of first electrodes 200 may be provided at fixed intervals by each first separating channel 210 interposed in-between.

The first separating channel 210 is formed in parallel to the arrangement direction of the plurality of through-holes 110 provided in the substrate 100. Especially, the first separating channel 210 is partially overlapped with the predetermined portion of the through-hole 110. That is, the plural through-holes 110 are overlapped with the predetermined portion of the first separating channel 210.

By the first separating channel 210, the one end 201 of each of the plural first electrodes 200 is formed on the partial portion of the inner surface of the through-hole 110 provided in the substrate 100; and the other end 202 of each of the plural first electrodes 200 is not extended to the inner surface of the through-hole 110 provided in the substrate 100, that is, the other end 202 is formed on the one surface of the substrate 100, for example, the upper surface of the substrate 100.

The process for forming the first separating channel 210 may be carried out by a laser-scribing process or chemical-etching process.

As shown in FIG. 5D, the semiconductor layer 300 is formed on the plurality of first electrodes 200.

The semiconductor layer 300 may be formed of the silicon-based material such as amorphous silicon by PECVD (Plasma Enhanced Chemical Vapor Deposition). In more detail, the N-type semiconductor layer is firstly formed using SiH₄, H₂, and PH₃ gas by PECVD; the I-type semiconductor layer is formed thereon using SiH₄ and H₂ gas by PECVD; and then the P-type semiconductor layer is formed thereon using SiH₄, H₂, and B₂H₆ gas, to thereby complete the semiconductor layer 300.

The process for forming the semiconductor layer 300 may comprise steps of forming the first semiconductor layer 301; forming the buffer layer 302 on the first semiconductor layer 301; and forming the second semiconductor layer 303 on the buffer layer 302. As mentioned above, the first and second semiconductor layers 301 and 303 may be formed by PECVD, and the buffer layer 302 may be formed by MOCVD.

When carrying out the PECVD process, the semiconductor layer 300 may be formed on the inner surface of the through-hole 110 provided in the substrate 100.

Then, as shown in FIG. 5E, a second electrode layer 400a is formed on the semiconductor layer 300.

The second electrode layer 400a may be formed of the transparent conductive material such as ZnO; ZnO doped with a material including Group III elements in the periodic table (for example, ZnO:B, ZnO:Al); ZnO doped with a material including hydrogen element (for example, ZnO:H); SnO₂; SnO₂:F; or ITO (Indium Tin Oxide) by MOCVD (Metal Organic Chemical Vapor Deposition) or by sputtering.

When carrying out the MOCVD process or sputtering process, the second electrode layer 400a may be formed on the inner surface of the through-hole 110 provided in the substrate 100.

As shown in FIG. 5F, the second separating channel 410 is formed by removing a predetermined portion from the second electrode layer 400a. The plurality of second electrodes 400 may be provided at fixed intervals by each second separating channel 410 interposed in-between.

The second separating channel 410 is formed in parallel to the arrangement direction of the plural through-holes 110 in the substrate 100. Especially, the second separating channel 410 is partially overlapped with the predetermined portion of the through-hole 110. The plurality of through-holes 110 are formed in such a manner that they are overlapped with the predetermined portion of the second separating channel 410.

Also, the second separating channel 410 is partially overlapped with the predetermined portion of the first separating channel 210. That is, the second separating channel 410 is overlapped with the predetermined portion of the first separating channel 210.

By the above structure of the second separating channel 410, the one end 401 of each of the plural second electrodes 400 is formed in the other portion of the inner surface of the through-hole 110, on which the one end 201 of the first electrode 200 is not formed. Also, the other end 402 of the second electrode 400 is not extended to the inner surface of the through-hole 110 provided in the substrate 100. Thus, the other end 402 of the second electrode 400 is formed on the one surface of the substrate 100, for example, the upper surface of the substrate 100.

The process of forming the second separating channel 410 may be carried out by the laser-scribing process or chemical-etching process.

As shown in FIG. 5G, the connecting portion 500 is formed on the other surface of the substrate 100.

The connecting portion 500 is extended in the same direction as the plurality of through-holes 110 provided in the substrate 100, whereby the connecting portion 500 is respectively connected with the one end 201 of the first electrode 200, and the one end 401 of the second electrode 400 extended to the inner surface of the through-hole 110 of the substrate 100.

The connecting portion 500 may be formed using paste of a conductive metal material such as Ag by the printing method such as the screen-printing method, inkjet-printing method, gravure-printing method, or micro-contact printing method, but it is not limited to these examples. The connecting portion 500 may be formed by MOCVD (Metal Organic Chemical Vapor Deposition) or by sputtering.

Although not shown, the transparent conductive layer may be additionally formed between the first electrode 200 and the semiconductor layer 300, or between the second electrode 400 and the semiconductor layer 300. The transparent conductive layer may be formed of the transparent conductive material such as ZnO; ZnO doped with a material including Group III elements in the periodic table (for example, ZnO:B, ZnO:Al); ZnO doped with a material including hydrogen elements (for example, ZnO:H); SnO₂; SnO₂:F; or ITO (Indium Tin Oxide) by MOCVD (Metal Organic Chemical Vapor Deposition) or by sputtering.

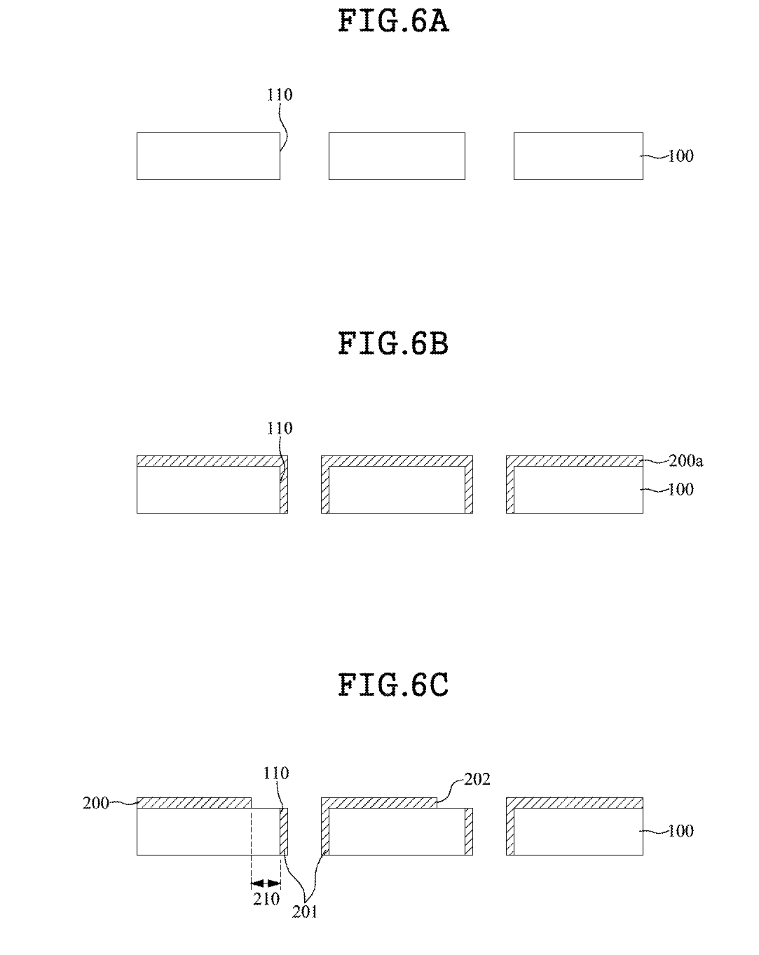

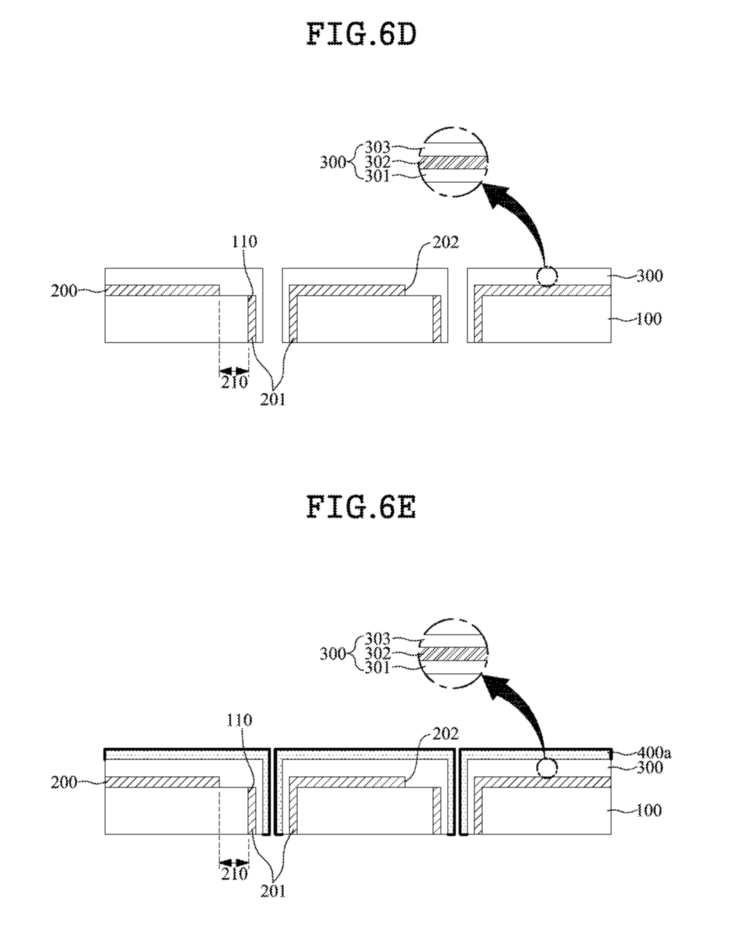

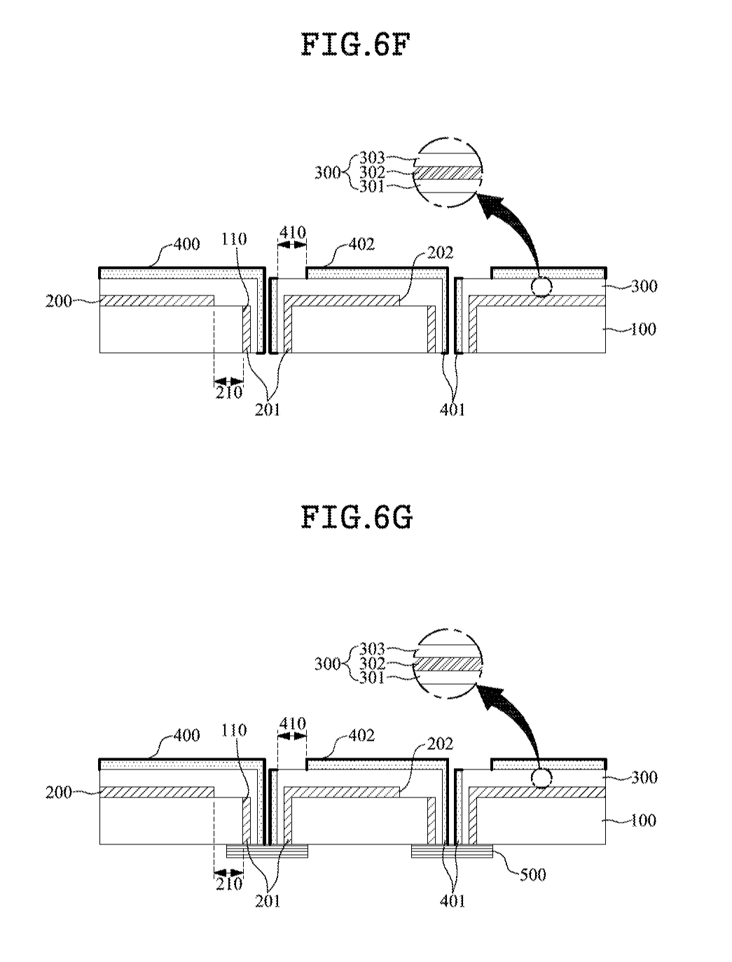

FIGS. 6A to 6G are cross section views illustrating a method for manufacturing the solar cell according to another embodiment of the present invention. FIGS. 6A to 6G illustrate a manufacturing process of the solar cell shown in FIGS. 4A to 4C, which are cross section views along A-A of FIG. 4A. Hereinafter, a detailed explanation for the same parts as those of the aforementioned embodiment of the present invention will be omitted.

First, as shown in FIG. 6A, the substrate 100 including the through-holes 110 is prepared.

Then, as shown in FIG. 6B, a first electrode layer 200a is formed on the one surface of the substrate 100, for example, the upper surface of the substrate 100.

As shown in FIG. 6C, the first separating channel 201 is formed by removing a predetermined portion from the first electrode layer 200a. Thus, the plurality of first electrodes 200 are provided at fixed intervals by each first separating channel 210 interposed in-between.

The first separating channel 210 is formed in parallel to the arrangement direction of the plural through-holes 110 in the substrate 100. Especially, the first separating channel 210 is not overlapped with the through-hole 110.

By the first separating channel 210, the one end 201 of each of the plural first electrodes 200 is formed on the entire inner surface of the through-hole 110 provided in the substrate 100; and the other end 202 of each of the plural first electrodes 200 is not extended to the inner surface of the through-hole 110. Thus, the other end 202 of the first electrode 200 is formed on the one surface of the substrate 100, for example, the upper surface of the substrate 100.

As shown in FIG. 6D, the semiconductor layer 300 is formed on the plurality of first electrodes 200.

Then, as shown in FIG. 6E, a second electrode layer 400a is formed on the semiconductor layer 300.

As shown in FIG. 6F, the second separating channel 410 is formed by removing a predetermined portion from the second electrode layer 400a. The plurality of second electrodes 400 are provided at fixed intervals by each second separating channel 410 interposed in-between.

The second separating channel 410 is formed in parallel to the arrangement direction of the plural through-holes 110. Especially, the second separating channel 410 is not overlapped with the through-hole 110. Also, the second separating channel 410 is not overlapped with the first separating channel 210.

By the second separating channel 410, the one end 401 of each of the plural second electrodes 400 is formed on the entire inner surface of the through-hole 110 provided in the substrate 100; and the other end 402 of each of the plural second electrodes 400 is not extended to the inner surface of the through-hole 110. Thus, the other end 402 of the second electrode 400 is formed on the one surface of the substrate 100, for example, the upper surface of the substrate 100.

As shown in FIG. 6G, the connecting portion 500 is formed on the other surface of the substrate 100.

The connecting portion 500 is formed in the same direction as the plurality of through-holes 110 provided in the substrate 100, whereby the connecting portion 500 is respectively connected with the one end 201 of the first electrode 200, and the one end 401 of the second electrode 400 extended to the inner surface of the through-hole 110 of the substrate 100.

Accordingly, the solar cell according to the present invention makes the electric connection between the first and second electrodes 200 and 400 via the through-hole 110 provided in the substrate 100 instead of the related art contact hole obtained by removing the semiconductor layer. Accordingly, the solar cell according to the present invention enables to improve the solar cell efficiency by preventing residual matters including semiconductor materials from remaining between the first and second electrodes 200 and 400, and preventing a contact resistance from being increased between the first and second electrodes 200 and 400 caused by the residual matters.

Even though the plural layers are deposited on the substrate 100 under the high-temperature condition, a stress concentration is mitigated by the through-hole 110 formed in the substrate 100 of the solar cell according to the present invention, to thereby minimize the sagging substrate. As a result, it is possible to improve uniformity in the plural layers deposited on the substrate 100.

The method for manufacturing the solar cell according to the present invention does not require the process for forming the contact hole by removing the semiconductor layer, whereby the manufacturing time is decreased by the decreased number of times of laser-scribing process. Also, the manufacturing cost is also lowered because the number of laser-scribing apparatuses is decreased. Even though the laser-scribing process is carried out, the laser-scribing process is applied to the first and second electrodes 200 and 400 which are formed of the similar material. That is, the laser-scribing apparatus using the same wavelength may be used so that the efficiency is considerably improved.

When the first and second separating channels 210 and 410 are overlapped with the through-hole 110, lowering of solar cell efficiency is minimized owing to the decrease of dead zone.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A solar cell comprising:
a substrate including a through-hole;
a first electrode on one surface of the substrate, wherein one end of the first electrode is on an inner surface of the through-hole;
a semiconductor layer on the first electrode;
a second electrode on the semiconductor layer, wherein one end of the second electrode is on the inner surface of the through-hole; and
a connecting portion for electrically connecting the one end of the first electrode with the one end of the second electrode.

2. The solar cell according to claim 1, wherein a plurality of first electrodes are provided at fixed intervals with a first separating channel between adjacent first electrodes; and a plurality of second electrodes are provided at fixed intervals with a second separating channel between adjacent second electrodes.

3. The solar cell according to claim 2, wherein the plurality of through-holes are arranged in parallel to the first and second separating channels.

4. The solar cell according to claim 3, wherein each of the plurality of through-holes overlaps (i) a portion of the first separating channel and (ii) a portion of the second separating channel; and the first separating channel overlaps a portion of the second separating channel.

5. The solar cell according to claim 3, wherein the plurality of through-holes do not overlap the first or second separating channels; and the first separating channel does not overlap the second separating channel.

6. The solar cell according to claim 1, wherein another end of the first electrode is on an uppermost surface of the substrate, and another end of the second electrode is on an uppermost surface of the semiconductor layer.

7. The solar cell according to claim 1, wherein the one end of the first electrode is on a first portion of the inner surface of the through-hole; and the one end of the second electrode is on a second portion of the inner surface of the through-hole different from the first portion of the inner surface of the through-hole.

8. The solar cell according to claim 1, wherein the one end of the first electrode is on a first entire inner surface of the through-hole; and the one end of the second electrode is on a second entire inner surface of the through-hole.

9. The solar cell according to claim 1, wherein the semiconductor layer is on the one end of the first electrode in the inner surface of the through-hole, under the second electrode.

10. The solar cell according to claim 1, wherein the semiconductor layer comprises:
an N-type semiconductor layer on the first electrode;
an I-type semiconductor layer on the N-type semiconductor layer; and
a P-type semiconductor layer on the I-type semiconductor layer.

11. The solar cell according to claim 1, wherein the semiconductor layer comprises first and second semiconductor layers, and a buffer layer between the first and second semiconductor layers.

12. The solar cell according to claim 1, wherein the connecting portion is on another surface of the substrate.

13. A method for manufacturing a solar cell comprising:
preparing a substrate including a through-hole;
forming a first electrode layer on one surface of the substrate including an inner surface of the through-hole;
forming a first electrode by removing a portion of the first electrode layer, wherein one end of the first electrode is formed on the inner surface of the through-hole;
forming a semiconductor layer on the first electrode;
forming a second electrode layer on the semiconductor layer;
forming a second electrode by removing a predetermined portion from the second electrode layer, wherein one end of the second electrode is formed on the inner surface of the through-hole; and
forming a connecting portion for electrically connecting the one end of the first electrode with the one end of the second electrode.

14. The method according to claim 13, wherein the process for preparing the substrate including the through-hole comprises forming a plurality of through-holes along a predetermined direction of the substrate,
removing the portion of the first electrode layer forms a first separating channel such that adjacent first electrodes are separated by a first predetermined interval, and removing the portion of the second electrode layer forms a second separating channel such that adjacent second electrodes are separated by a second predetermined interval, wherein the first and second separating channels are formed in parallel to the arrangement direction of the through-holes.

15. The method according to claim 14, wherein the first and second separating channels partially overlap with one of the plurality of through-holes; and the second separating channel partially overlaps with the first separating channel.

16. The method according to claim 14, wherein the first and second separating channels do not overlap with the plurality of through-holes; and the second separating channel does not overlap with the first separating channel.

17. The method according to claim 13, wherein another end of the first electrode is formed on an uppermost surface of the substrate; and another end of the second electrode is formed on an uppermost surface of the semiconductor layer.

18. The method according to claim 13, wherein the one end of the first electrode is formed on a first portion of the inner surface of the through-hole; and the one end of the second electrode is formed on a second portion of the inner surface of the through-hole, different from the first portion of the inner surface of the through-hole.

19. The method according to claim 13, wherein the one end of the first electrode is formed on a first entire inner surface of the through-hole; and the one end of the second electrode is formed on a second entire inner surface of the through-hole.

20. The method according to claim 13, wherein the semiconductor layer is formed on the one end of the first electrode in the inner surface of the through-hole, and the one end of the second electrode is formed on the semiconductor layer.

21. The method according to claim 13, wherein the process for forming the semiconductor layer comprises:
forming an N-type semiconductor layer on the first electrode;
forming an I-type semiconductor layer on the N-type semiconductor layer; and
forming a P-type semiconductor layer on the I-type semiconductor layer.

22. The method according to claim 13, wherein the process for forming the semiconductor layer comprises:
forming a first semiconductor layer on the first electrode;
forming a buffer layer on the first semiconductor layer; and
forming a second semiconductor layer on the buffer layer.
